(19) United States
(12) Patent Application Publication
(10) Pub. No.: US 2010/0321279 A1
(43) Pub. Date: Dec. 23, 2010

(54) Transistor, electronic device including a transistor and methods of manufacturing the same

(75) Inventors: Ji-sim Jung, Incheon (KR); Sang-yoon Lee, Seoul (KR); Kwang-hee Lee, Suwon-si (KR); Jang-yeon Kwon, Seongnam-si (KR); Kyoung-seok Son, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,914

(22) Filed: Dec. 4, 2009

(30) Foreign Application Priority Data
Jun. 17, 2009 (KR) 10-2009-0053988

(51) Int. Cl. G09G 3/30; H01L 29/12; H01L 29/786; G09G 3/20

(52) U.S. Cl. 345/76; 257/43; 257/57; 345/55; 257/E29.068; 257/E29.296

(57) ABSTRACT

Disclosed are a transistor, an electronic device and methods of manufacturing the same, the transistor including a photo relaxation layer between a channel layer and a gate insulating layer in order to suppress characteristic variations of the transistor due to light. The photo relaxation layer may be a layer of a material capable of suppressing variations in a threshold voltage of the transistor due to light. The photo relaxation layer may contain a metal oxide such as aluminum (Al) oxide. The channel layer may contain an oxide semiconductor.

### CROSS-REFERENCE TO RELATED APPLICATION

This application claims the benefit of priority under 35 U.S.C. §119 from, Korean Patent Application No. 10-2009-0053988, filed on Jun. 17, 2009, in the Korean Intellectual Property Office, the disclosure of which is incorporated herein in its entirety by reference.

### BACKGROUND

1. Field

Example embodiments relate to a transistor, an electronic device including a transistor and methods of manufacturing the same.

2. Description of the Related Art

Transistors may be used as switching devices, or driving devices, in electronic devices. In particular, because thin film transistors may be formed on glass substrates or plastic substrates, they are generally used in the field of flat panel display devices (e.g., liquid crystal display (LCD) devices and organic light emitting display (OLED) devices) or similar imaging devices.

A method of using an oxide layer having a high carrier mobility as a channel layer may be used to increase the operational characteristics of a transistor. This method is generally used for forming a thin film transistor for a flat panel display device.

However, the characteristics of a transistor having an oxide layer as a channel layer may not be constantly maintained because the oxide layer is sensitive to light.

### SUMMARY

Example embodiments relate to a transistor, an electronic device including a transistor and methods of manufacturing the same.

Example embodiments include a transistor of which characteristic variations due to light are suppressed and a method of manufacturing the transistor.

Example embodiments include an electronic device including the transistor.

Additional aspects will be set forth in part in the description which follows and, in part, will be apparent from the description, or may be learned by practice of the presented embodiments.

According to example embodiments, a transistor includes a source, a drain, a channel layer, a gate insulating layer and a gate. The channel layer includes an oxide semiconductor. A photo relaxation layer including a metal oxide (e.g., aluminum (Al) oxide) may be formed between the channel layer and the gate insulating layer in order to suppress characteristic variations of the transistor due to light. The photo relaxation layer may suppress variations in a threshold voltage of the transistor due to light. The photo relaxation layer may include, or consist, of a material that suppresses variations in a threshold voltage of the transistor due to light.

The photo relaxation layer may be formed of aluminum oxide (Al₂O₃). The photo relaxation layer may have a thickness of about 1-nm to about 50-nm.

The oxide semiconductor may be a zinc oxide (ZnO)-based oxide. The ZnO-based oxide may be HfInZnO.

The gate insulating layer may include silicon (Si) nitride. The gate insulating layer may include Si oxide. The gate insulating layer may have a thickness of about 50-nm to about 400-nm.

The transistor may be a bottom-gate thin film transistor or a top-gate thin film transistor. The transistor may include an etch stop layer on the channel layer if the transistor is the bottom-gate thin film transistor. In this case, the source and the drain may be formed on the etch stop layer to separately contact two ends of the channel layer.

According to example embodiments, a flat panel display device may include the above-described transistor. The flat panel display device may be a liquid crystal display (LCD) device or an organic light emitting display (OLED) device.

The transistor may be used as a switching device or a driving device.

### BRIEF DESCRIPTION OF THE DRAWINGS

These and/or other aspects will become apparent and more readily appreciated from the following description of the embodiments, taken in conjunction with the accompanying drawings of which:

FIGS. 1 through 3 are cross-sectional diagrams of transistors according to example embodiments;

FIGS. 4A through 4C are cross-sectional diagrams for describing a method of manufacturing a transistor according to example embodiments;

FIGS. 5A through 5C are cross-sectional diagrams for describing a method of manufacturing a transistor according to example embodiments;

FIG. 6 is a graph showing variations in gate voltage-drain current characteristics of a transistor according to a comparative example due to light irradiation;

FIG. 7 is a graph showing variations in gate voltage-drain current characteristics of a transistor according to example embodiments due to light irradiation;

FIG. 8 is a graph showing variations in characteristics of a transistor according to example embodiments and a transistor according to a comparative example based on time when light is irradiated onto the transistors and then is blocked; and

FIG. 9 is a graph showing variations in characteristics of a transistor according to example embodiments and a transistor according to a comparative example due to light irradiation and voltage stress.

### DETAILED DESCRIPTION

Various example embodiments will now be described more fully with reference to the accompanying drawings in which some example embodiments are shown.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the thicknesses of layers and regions are exaggerated for clarity. Like reference numerals in the drawings denote like elements.

Example embodiments relate to a transistor, an electronic device including a transistor and methods of manufacturing the same.

FIG. 1 is a cross-sectional diagram of a transistor according to example embodiments. The transistor shown in FIG. 1 is a bottom-gate thin film transistor in which a gate G1 is formed below a channel layer C1.

Referring to FIG. 1, the gate G1 may be formed on a substrate SUB1. The substrate SUB1 may be a glass substrate or other substrates generally used in a semiconductor device, for example, a plastic substrate or a silicon (Si) substrate. The gate G1 may be formed of an electrode material (e.g., a metal). A gate insulating layer GI1 may be formed on the substrate SUB1 and covering the gate G1. The gate insulating layer GI1 may be a silicon (Si) nitride layer, an Si oxide layer or similar material layer. A photo relaxation layer R1 may be formed on the gate insulating layer GI1. The photo relaxation layer R1 will be described in detail later.

The channel layer C1 may be formed on the photo relaxation layer R1. The channel layer C1 may be formed above the gate G1. A width of the channel layer C1, along the direction of the x-axis, may be greater than a width of the gate G1 along the direction of the x-axis. The channel layer C1 may contain an oxide semiconductor (e.g., a zinc oxide (ZnO)-based oxide semiconductor). If the channel layer C1 includes a ZnO-based oxide semiconductor, the channel layer C1 may further include a Group III element (e.g., indium (In) or gallium (Ga)), a Group IV element (e.g., tin (Sn)), a transition metal (e.g., hafnium (Hf)) or another element. For example, the channel layer C1 according to example embodiments may be an HfInZnO layer. The oxide semiconductor may be in an amorphous or crystalline phase, or a mixed amorphous-crystalline phase. If the channel layer C1 is formed of an oxide semiconductor, the channel layer C1 may be formed at low temperature without performing a high-temperature process for crystallization and activation. Also, because the mobility of an oxide semiconductor is several to several ten times higher than that of amorphous Si or polycrystalline Si, a high-speed transistor may be realized by using an oxide semiconductor layer.

Source and drain electrodes S1 and D1 may be formed on the photo relaxation layer R1 to separately contact two ends of the channel layer C1. The source and drain electrodes S1 and D1 may be formed as a single metal layer, or multiple metal layers. The source and drain electrodes S1 and D1 and the gate G1 may be formed as the same metal layer, or different metal layers. A surface portion of the channel layer C1, which is not covered by the source and drain electrodes S1 and D1, may be a region treated with a plasma containing oxygen. A passivation layer P1 may be formed on the photo relaxation layer R1 and covering the channel layer C1 and the source and drain electrodes S1 and D1. The passivation layer P1 may be formed to have a monolayer, or multilayer, structure including at least one of the group consisting of an Si oxide layer, an Si nitride layer, an organic layer and combinations thereof. The thicknesses of the gate G1, the gate insulating layer GI1, the source electrode S1 and the drain electrode D1 may respectively be about 50-nm to about 300-nm, about 50-nm to about 400-nm, about 10-nm to about 200-nm, and about 10-nm to about 200-nm.

The photo relaxation layer R1 will now be described in detail.

The photo relaxation layer R1 is formed between the channel layer C1 and the gate insulating layer GI1. The photo relaxation layer R1 suppresses, or prevents, characteristic variations of the transistor due to light. If light is irradiated onto the channel layer C1, excess charges may be generated from the channel layer C1 and thus the characteristics of the transistor may vary. It is assumed that the photo relaxation layer R1 suppresses, or prevents, the characteristic variations of the transistor by preventing the formation of trap sites in which the excess charges, i.e., carriers (e.g., electrons or holes) may be trapped. The photo relaxation layer R1 may be, for example, an insulating material layer containing aluminum (Al) oxide (e.g., Al₂O₃). A metal oxide may have insulating characteristics, semiconductor characteristics or conductor characteristics according to its composition. A material for forming the photo relaxation layer R1 may have a composition that represents insulating characteristics. The thickness of the photo relaxation layer R1 may be, for example, about 1-nm to about 50-nm.

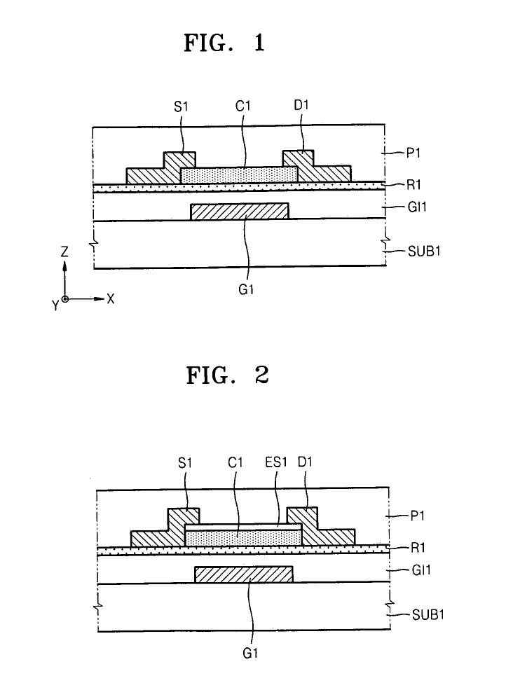

FIG. 2 is a cross-sectional diagram of a bottom-gate transistor according to example embodiments.

Like reference numerals in FIG. 1 and FIG. 2 denote like elements, and thus a description of the like elements will be omitted for the sake of brevity.

Referring to FIG. 2, an etch stop layer ES1 may be formed on the channel layer C1 such that the etch stop layer ES1 is between the channel layer C1 and the source and drain electrodes S1 and D1.

The source and drain electrodes S1 and D1 may be formed on the etch stop layer ES1 to separately contact two ends of the channel layer C1. The etch stop layer ES1 may prevent the channel layer C1 from being damaged during an etching process for forming the source and drain electrodes S1 and D1. The etch stop layer ES1 may contain, for example, Si nitride, Si oxide or an organic insulator. Whether to form the etch stop layer ES1, or not, may be determined based on the material used to form the channel layer C1 and the material used to form the source and drain electrodes S1 and D1.

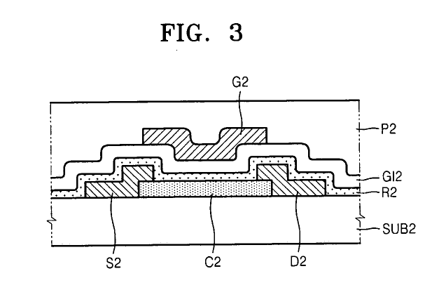

FIG. 3 is a cross-sectional diagram of a transistor according to example embodiments. The transistor according to example embodiments is a top-gate thin film transistor in which a gate G2 is formed above a channel layer C2.

Referring to FIG. 3, the channel layer C2 may be formed on a substrate SUB2. Source and drain electrodes S2 and D2 may be formed on the substrate SUB2 to separately contact two ends of the channel layer C2. A surface portion of the channel layer C2, which is not covered by the source and drain electrodes S2 and D2, may be a region treated with a plasma containing oxygen. A photo relaxation layer R2 may be formed on the substrate SUB2. The photo relaxation layer R2 may cover the channel layer C2 and the source and drain electrodes S2 and D2. A gate insulating layer GI2 may be formed on the photo relaxation layer R2. The gate G2 may be formed on the gate insulating layer GI2. The gate G2 may be located above the channel layer C2. A passivation layer P2 may be formed on the gate insulating layer GI2 and covering the gate G2. Materials and thicknesses of the substrate SUB2, the channel layer C2, the source electrode S2, the drain electrode D2, the photo relaxation layer R2, the gate insulating layer GI2, the gate G2, and the passivation layer P2 illustrated in FIG. 3 may be respectively the same as those of the substrate SUB1, the channel layer C1, the source electrode S1, the drain electrode D1, the photo relaxation layer R1, the gate insulating layer GI1, the gate G1 and the passivation layer P1 described above with reference to FIG. 1.

An etch stop layer (not shown) may be formed on the channel layer C2 such that the etch stop layer is between the channel layer C2 and the source and drain electrodes S2 and D2.

A method of manufacturing a bottom-gate thin film transistor will now be described.

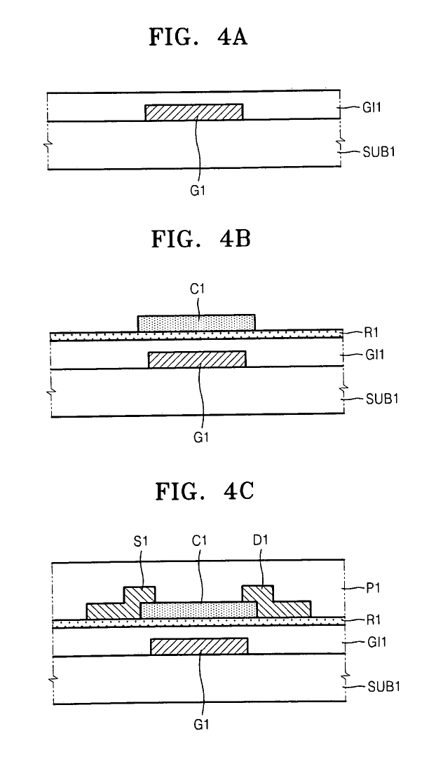

FIGS. 4A through 4C are cross-sectional diagrams for describing a method of manufacturing a transistor according to example embodiments. Like reference numerals in FIG. 1 and FIGS. 4A through 4C denote like elements, and thus a description of the like elements in some instances may be omitted for the sake of brevity.

Referring to FIG. 4A, a gate G1 may be formed on a substrate SUB1 and subsequently a gate insulating layer GI1 may be formed on the substrate SUB1 and covering the gate G1. The gate insulating layer GI1 may be formed of Si nitride, Si oxide or another material. The thickness of the gate insulating layer GI1 may be, for example, about 50-nm to about 400-nm.

Referring to FIG. 4B, a photo relaxation layer R1 may be formed on the gate insulating layer GI1. The photo relaxation layer R1 may be formed using a physical vapor deposition (PVD) method (e.g., a sputtering method and an evaporation method), or an oxidation method. For example, the photo relaxation layer R1 may be formed of an insulating material containing aluminum (Al) oxide (e.g., Al₂O₃). The thickness of the photo relaxation layer R1 may be about 1-nm to about 50-nm.

A channel layer C1 may be formed on the photo relaxation layer R1. The channel layer C1 and the photo relaxation layer R1 may be sequentially, and/or consecutively, formed. The channel layer C1 may be located above the gate G1. The channel layer C1 may be formed of an oxide semiconductor (e.g., a ZnO-based oxide semiconductor). The ZnO-based oxide semiconductor may further contain a Group III element (e.g., indium (In), gallium (Ga) or combinations thereof), a Group IV element (e.g., tin (Sn)), a transition metal (e.g., hafnium (Hf)), or another element. For example, the channel layer C1 may be formed of an alloy (e.g., HfInZnO). The oxide semiconductor may be in an amorphous or crystalline phase, or a mixed amorphous-crystalline phase. If the channel layer C1 is formed of an oxide semiconductor, the channel layer C1 may be formed at low temperature without performing a high-temperature process for crystallization and activation.

Referring to FIG. 4C, source and drain electrodes S1 and D1 may be formed on the photo relaxation layer R1 to separately contact two ends of the channel layer C1 and to expose a portion of an upper surface of the channel layer C1. The source and drain electrodes S1 and D1 may be formed as a single metal layer, or multiple metal layers. The source and drain electrodes S1 and D1 and the gate G1 may be formed as the same metal layer, or different metal layers. A passivation layer P1 may be formed on the photo relaxation layer R1 and covering the exposed portion of the channel layer C1 and the source and drain electrodes S1 and D1. The passivation layer P1 may be formed to have a monolayer, or multilayer, structure including at least one of the group consisting of an Si oxide layer, an Si nitride layer and an organic layer. Before depositing the passivation layer P1, the exposed portion of the channel layer C1 may be treated with a plasma containing oxygen. Due to the plasma processing, oxygen may be provided to the exposed portion of the channel layer C1, and thus the electrical conductivity of the channel layer C1 may be controlled. The transistor formed as described above may be annealed at a given temperature. The annealing may be performed under an air atmosphere or a nitrogen (N₂) and oxygen (O₂) atmosphere. The annealing may be performed at about 200° C. to 400° C. for about 1-hour to about 100 hours.

Although not shown in FIG. 4C, before forming the source and drain electrodes S1 and D1, an etch stop layer (as shown in FIG. 2) may be formed on the upper surface of the channel layer C1.

A method of manufacturing a top-gate thin film transistor will now be described.

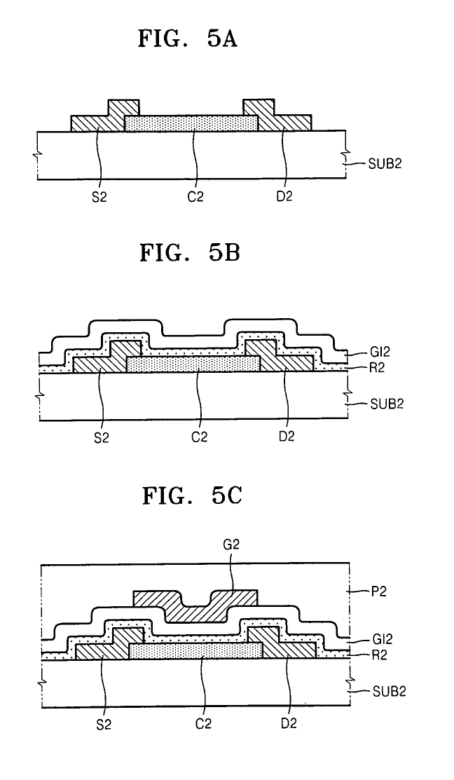

FIGS. 5A through 5C are cross-sectional diagrams for describing a method of manufacturing a transistor according to example embodiments. Like reference numerals in FIG. 3 and FIGS. 5A through 5C denote like elements, and thus a description thereof in some instances may be omitted for the sake of brevity.

Referring to FIG. 5A, a channel layer C2 may be formed on a substrate SUB2. The channel layer C2 may be formed of the same material as the channel layer C1 illustrated in FIG. 4B. Source and drain electrodes S2 and D2 may be formed on the substrate SUB2 to separately contact two ends of the channel layer C2. If necessary, an exposed portion of the channel layer C2, which is not covered by the source and drain electrodes S2 and D2, may be treated with a plasma containing oxygen.

Referring to FIG. 5B, a photo relaxation layer R2 may be formed on the substrate SUB1 and covering the exposed portion of the channel layer C2 and the source and drain electrodes S2 and D2. A gate insulating layer GI2 may be formed on the photo relaxation layer R2. Forming methods, materials, and thicknesses of the gate insulating layer GI2 and the photo relaxation layer R2 may be respectively the same as those of the gate insulating layer GI1 and the photo relaxation layer R1 illustrated in FIGS. 4A and 4B.

Referring to FIG. 5C, a gate G2 may be formed on the gate insulating layer GI2. The gate G2 may be located above the channel layer C2. A passivation layer P2 may be formed on the gate insulating layer GI2 to cover the gate G2. The passivation layer P2 may be formed of the same material as the passivation layer P1 illustrated in FIG. 4C. The transistor formed as described above may be annealed at a given temperature, and the annealing conditions may be the same as those described above with reference to FIG. 4C.

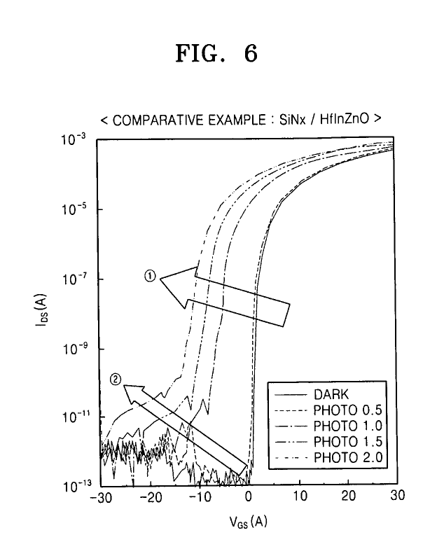

FIG. 6 is a graph showing variations in gate voltage V_{GS}-drain current I_{DS} characteristics of a transistor according to a comparative example due to light irradiation. The transistor according to the comparative example has the structure of the transistor of FIG. 1, without the photo relaxation layer R1. In this case, an Si nitride (SiNₓ) layer is used as a gate insulating layer and a HfInZnO layer is used as a channel layer.

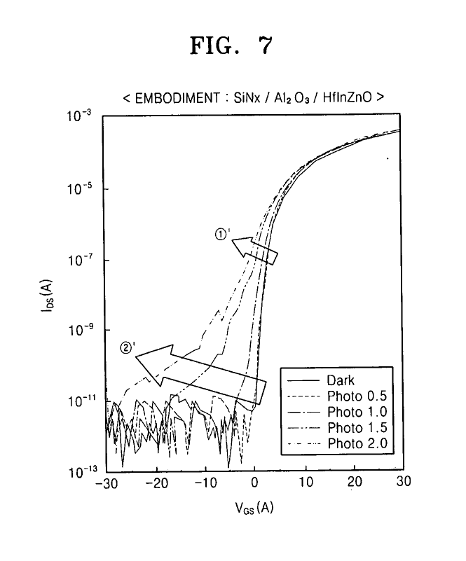

In FIG. 6, ‘Photo 0.5’, ‘Photo 1.0’, ‘Photo 1.5’, and ‘Photo 2.0’ represent relative intensities of irradiated light. For example, ‘Photo 1.0’ represents irradiated light with an intensity that is twice greater than that of ‘Photo 0.5’. ‘Dark’ represents a case when no light is irradiated. These marks are also applied to the graph of FIG. 7.

Light is irradiated onto the transistor from above the passivation layer.

Referring to FIG. 6, as the intensity of irradiated light increases, a plotted line moves to the left of the graph. That is, as the intensity of irradiated light increases, a threshold voltage of the transistor moves in a negative (−) direction and a subthreshold current of the transistor is increased. An arrow (1) represents variations in a threshold voltage and an arrow (2) represents variations in a subthreshold current.

FIG. 7 is a graph showing variations in gate voltage V_{GS}-drain current I_{DS} characteristics of a transistor according to example embodiments due to light irradiation. The transistor used for the results of FIG. 7 is the transistor illustrated in FIG. 1. In this case, an Si nitride (SiNₓ) layer is used as the gate insulating layer GI1, an Al₂O₃ layer is used as the photo relaxation layer R1 and a HfInZnO layer is used as the channel layer C1. That is, the transistor used for the results of FIG. 7 is the same as the transistor used for the results of FIG. 6, except that the photo relaxation layer R1 is used.

Referring to FIG. 7, as the intensity of irradiated light increases, a subthreshold current is increased similarly to FIG. 6 while variations in a threshold voltage are relatively very small. An arrow (2)′ represents variations in a threshold voltage and an arrow (1)′ represents variations in a subthreshold current.

The results of FIGS. 6 and 7 show that variations in characteristics (for example, variations in threshold voltage) of a transistor due to light may be suppressed if a photo relaxation layer is used as illustrated in FIG. 7.

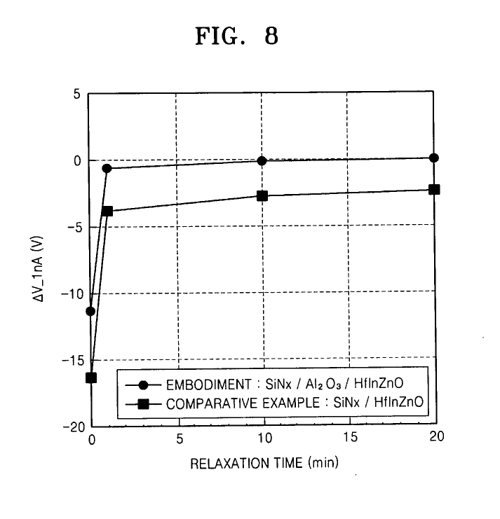

FIG. 8 is a graph showing variations in characteristics of a transistor according to example embodiments and a transistor according to a comparative example based on time if light is irradiated onto the transistors and then is blocked. In this case, light irradiated onto the transistors has an intensity corresponding to ‘Photo 2.0’ of FIG. 6. The transistor according to example embodiments is the same as the transistor used for the results of FIG. 7 and the transistor according to the comparative example is the same as the transistor used for the results of FIG. 6. In FIG. 8, an x-axis represents time after light is blocked and a y-axis (i.e., “ΔV_{—}1 nA” represents a difference in ‘V_{—}1 nA’ between before and after light is irradiated ([V_{—}1 nA (after)−V_{—}1 nA (before)]). Here, ‘V_{—}1 nA’ represents a gate voltage for allowing a current of 1-nA to flow between a source and a drain.

Referring to FIG. 8, in the transistor according to example embodiments, “Δ V_{—}1 nA” rapidly approaches 0 V after light is blocked. After light is blocked, “ΔV_{—}1 nA” is almost 0 V at about one minute, and is 0 V at about ten minutes. As such, after light is blocked, the characteristics of the transistor rapidly return to a state before light is irradiated. On the other hand, in the transistor according to the comparative example, “ΔV_{—}1 nA” is maintained at about −3V at about twenty minutes after light is blocked. As such, in the transistor according to the comparative example, the characteristics that vary due to light are maintained for a relatively long time.

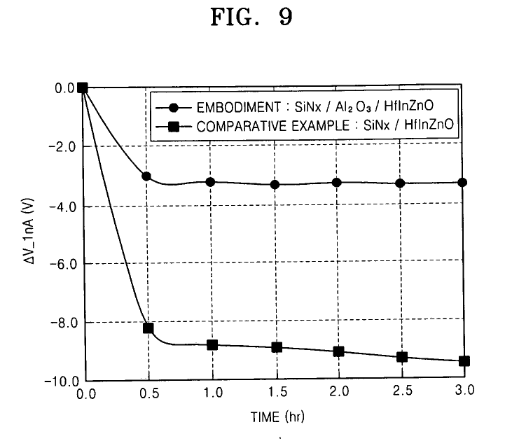

FIG. 9 is a graph showing variations in characteristics of a transistor according to example embodiments and a transistor according to a comparative example due to light irradiation and voltage stress. In more detail, the variations in characteristics (“ΔV_{—}1 nA”) of the transistors are measured according to time by irradiating light corresponding to ‘Photo 0.5’ of FIG. 6 while respectively applying −20V and 10V to a gate and a drain. In this case, the transistor according to example embodiments is the same as the transistor used for the results of FIG. 7, and the transistor according to the comparative example is the same as the transistor used for the results of FIG. 6.

Referring to FIG. 9, in the transistor according to the comparative example, after light is irradiated under voltage stress, ΔV_{—}1 nA is reduced to about −9.0V in about half an hour and is reduced to about −9.5V in about three hours. Thus, in the transistor according to the comparative example, a threshold voltage varies by about 9.0V at about half an hour after light is irradiated under voltage stress. On the other hand, in the transistor according to example embodiments, variations in V_{—}1 nA are relatively smaller. Thus, in the transistor according to example embodiments, variations in a threshold voltage due to light irradiation is substantially smaller even under voltage stress.

The transistor according to example embodiments may be used as a switching device or a driving device in flat panel display devices (e.g., liquid crystal display (LCD) devices and organic light emitting display (OLED) devices). As described above, the transistor according to example embodiments has small characteristic variations due to light and thus the reliability of a flat panel display device including the transistor increases. The structures of LCD devices and OLED devices are well known, and thus detailed descriptions thereof will be omitted. The transistor according to example embodiments may be used for various purposes in other electronic devices (e.g., memory devices and logic devices), as well as flat panel display devices.

It should be understood that the example embodiments described herein should be considered in a descriptive sense only and not for purposes of limitation. For example, it will be understood by one of ordinary skill in the art that the components and the structures of the transistors illustrated in FIGS. 1 through 3 may be modified and changed. The transistor according to example embodiment may have a double-gate structure and the channel layer C1 illustrated in FIG. 1 and the channel layer C2 illustrated in FIG. 3 may have a multilayer structure. Also, it will be understood by one of ordinary skill in the art that the method of FIGS. 4A through 4C and the method of FIGS. 5A through 5C may also be variously changed. Furthermore, example embodiments may also be applied to various transistors as well as thin film transistors. Descriptions of features or aspects within each embodiment should typically be considered as available for other similar features or aspects in other embodiments.

What is claimed is:

1. A transistor, comprising:
a source and a drain;
a channel layer on the source and drain, the channel layer including an oxide semiconductor;
a photo relaxation layer on the channel layer, wherein the photo relaxation layer includes aluminum (Al) oxide;
a gate insulating layer on the photo relaxation layer, wherein the photo relaxation layer is between the channel layer and the gate insulating layer in order to suppress characteristic variations of the transistor due to light; and
a gate on the gate insulating layer.

2. The transistor of claim 1, wherein the photo relaxation layer consists of a material capable of suppressing variations in a threshold voltage of the transistor due to the light.

3. The transistor of claim 1, wherein the aluminum (Al) oxide is Al₂O₃.

4. The transistor of claim 1, wherein the photo relaxation layer has a thickness of about 1-nm to about 50-nm.

5. The transistor of claim 1, wherein the oxide semiconductor is a zinc oxide (ZnO)-based oxide.

6. The transistor of claim 5, wherein the ZnO-based oxide is HfInZnO.

7. The transistor of claim 1, wherein the gate insulating layer includes silicon (Si) nitride.

8. The transistor of claim 1, wherein the gate insulating layer includes Si oxide.

9. The transistor of claim 1, wherein the gate insulating layer has a thickness of about 50-nm to about 400-nm.

10. The transistor of claim 1, wherein the transistor is a top-gate thin film transistor.

11. The transistor of claim 1, wherein the transistor is a bottom-gate thin film transistor.

12. The transistor of claim 11, further comprising an etch stop layer on the channel layer,
wherein the source and the drain are on the etch stop layer and separately contact separate ends of the channel layer.

13. The transistor of claim 1, further comprising an etch stop layer on the channel layer, wherein the source and the drain are on the etch stop layer and separately contact separate ends of the channel layer.

14. A flat panel display device, comprising the transistor of claim 1.

15. The flat panel display device of claim 14, wherein the flat panel display device is one selected from the group consisting of a liquid crystal display (LCD) device and an organic light emitting display (OLED) device.

16. The flat panel display device of claim 14, wherein the transistor is configured as a switching device or a driving device.

17. The flat panel display device of claim 14, wherein the photo relaxation layer includes a material capable of suppressing variations in a threshold voltage of the transistor due to the light.

18. The flat panel display device of claim 14, wherein the aluminum (Al) oxide is Al₂O₃.
